(19) United States
(12) Patent Application Publication
(10) Pub. No.: US 2011/0026233 A1
(43) Pub. Date: Feb. 3, 2011

(54) Apparatus and method for manufacturing elastic cable and electronic device using the same

(75) Inventors: Soon Min Hong, Seoul (KR); Ja Myeong Koo, Nam-gu (KR); Young Jun Moon, Hwaseong-si (KR); Sun Gu Yi, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/801,829

(22) Filed: Jun. 28, 2010

(30) Foreign Application Priority Data
Jul. 30, 2009 (KR) 10-2009-0069938

(51) Int. Cl. H05K 1/14; H05K 7/00; G05G 15/06; H01B 13/008

(52) U.S. Cl. 361/784; 361/679.01; 156/361; 156/50

(57) ABSTRACT

Disclosed herein is an apparatus for manufacturing an elastic cable including conductor tracks arranged in a zigzag shape between elastic films. The apparatus may include a conductor track supplying unit to supply at least one conductor track, an aligning unit to align the at least one conductor track supplied from the conductor track supplying unit, a film supplying unit to supply elastic films such that the at least one conductor track is surrounded by the elastic films, and a thermal lamination roller unit to thermally laminate the at least one conductor track arranged between the elastic films, wherein the aligning unit is reciprocally movable to arrange the at least one conductor track in a zigzag shape between the elastic films when the at least one conductor track is supplied to the thermal lamination roller unit.

### CROSS-REFERENCE TO RELATED APPLICATION

This application claims priority under 35 U.S.C. §119 to Korean Patent Application No. 2009-69938, filed on Jul. 30, 2009 in the Korean Intellectual Property Office (KIPO), the entire contents of which are incorporated herein by reference.

### BACKGROUND

1. Field

Example embodiments relate to an elastic cable exhibiting improved flexibility and operability while having a simple structure. Example embodiments also relate to an apparatus and method for manufacturing the same, and an electronic device using the same.

2. Description of the Related Art

Multi-pin cables may have a relatively miniature and thin structure and may be relatively bendable due to being made of a ductile material such as polyimide or polyethylene terephthalate (PET). In this case, a multi-pin cable may be useful in an electronic/electric device having an operating part, for example, a mobile phone, a robot, or a camcorder. Currently, the use of such a multi-pin cable is increasing.

However, the multi-pin cable, which is made of the above-mentioned material, does not have elasticity even though it exhibits ductility to tolerate bending. For this reason, when the multi-pin cable is used in an environment where external stress such as tensile, compressive, or torsional stress is applied to the multi-pin cable, degradation in reliability and space efficiency may be encountered.

### SUMMARY

Example embodiments provide an elastic cable exhibiting improved durability against external stresses such as bending, tension, compression, and torsion. Example embodiments also provide an apparatus and method for manufacturing the same, and an electronic device using the same.

Example embodiments will be set forth in part in the description which follows and, in part, will be obvious from the description, or may be learned by practice of example embodiments.

In accordance with example embodiments, an apparatus for manufacturing an elastic cable may include a conductor track supplying unit to supply at least one conductor track, an aligning unit to align the at least one conductor track supplied from the conductor track supplying unit, a film supplying unit to supply elastic films such that the at least one conductor track is surrounded by the elastic films, and a thermal lamination roller unit to thermally laminate the at least one conductor track arranged between the elastic films, wherein the aligning unit is reciprocally movable to arrange the at least one conductor track in a zigzag shape between the elastic films when the at least one conductor track is supplied to the thermal lamination roller unit.

In accordance with example embodiments, an electronic appliance may include a fixed unit, a movable unit coupled to the fixed unit such that the movable unit is movable with respect to the fixed unit, and an elastic cable connecting the fixed unit and the movable unit, wherein the elastic cable includes a plurality of conductor tracks arranged in parallel in a width direction in a zigzag shape between elastic films.

In accordance with example embodiments, a method for manufacturing an elastic cable including a plurality of conductor tracks and elastic insulating films may include supplying the plurality of conductor tracks, aligning the plurality of conductor tracks by an aligning unit such that the plurality of conductor tracks are uniformly spaced apart from one another, supplying the elastic films such that the elastic films support the plurality of conductor tracks, supplying the plurality of conductor tracks supported by the elastic films to a thermal lamination roller unit, and laterally reciprocating the aligning unit while applying a constant tension to the plurality of conductor tracks.

In accordance with example embodiments, an apparatus for manufacturing an elastic cable may include a conductor track supplying unit to supply one or more conductor tracks, an aligning unit to align the conductor tracks supplied from the conductor track supplying unit, a film supplying unit to supply elastic films such that the conductor tracks are surrounded by the elastic films, and a thermal lamination roller unit to thermally laminate the conductor tracks arranged in parallel between the elastic films, wherein the aligning unit is reciprocally movable to arrange the conductor tracks in a zigzag shape between the elastic films when the conductor tracks are supplied to the thermal lamination roller unit.

The aligning unit may include a base frame, and an aligner arranged at the base frame, to adjust a spacing between adjacent ones of the conductor tracks arranged in parallel between the elastic films while tensing the conductor tracks when the conductor tracks are supplied to the thermal lamination roller unit.

At least one of the base frame and the aligner may be laterally reciprocable.

The aligner may include a plurality of pressing rollers arranged on an upper surface of the base frame while being spaced apart from one another by a predetermined distance.

The reciprocable aligning unit may have a variable moving speed.

Each of the conductor tracks may be a conductive metal wire.

Each of the conductor tracks may be a conductive yarn including a core made of a non-conductive fiber or a polymer thread, and a conductive metal coated over a surface of the core.

Each of the conductor tracks may be a conductive metal wire surrounded by a non-conductive material.

Each of the conductor tracks may include an elastic core, and a conductive metal wire wound around the core.

The elastic films may be made of elastic polymer, rubber, or a composite thereof.

The thermal lamination roller unit may include thermal lamination rollers maintained at 80 to 300° C.

The zigzag shape may be formed in accordance with variations in a lateral moving speed and length of the aligning unit and a rotation speed of the thermal lamination roller unit.

The film supplying unit may be provided in plural to supply films, which will form a plurality of layers. The conductor track supplying unit may be provided in plural to supply the conductor tracks between adjacent ones of the films. The aligning unit may be provided in plural to align the conductor tracks supplied between the adjacent films.

The apparatus may further include an adhesive coater to coat an adhesive between the elastic films.

In accordance with example embodiments, an electronic appliance may include a fixed unit, and a movable unit coupled to the fixed unit such that the movable unit is movable with respect to the fixed unit, wherein the fixed unit and the movable unit are connected by an elastic cable, and the elastic cable includes a plurality of conductor tracks arranged in parallel in a width direction in a zigzag shape between elastic films.

The electronic appliance may be one of a mobile phone, a camcorder, a notebook, and a robot arm.

The movable unit may be rotatable about a rotating shaft in a swivel type with respect to the fixed unit.

The movable unit may be rotatable about a rotating shaft in a folder type with respect to the fixed unit.

The movable unit may be rotatable in a state of being separated from the fixed unit, and may be again coupled to the fixed unit after the rotation.

The fixed unit may include a main board to supply electric power and to generate control signals. The movable unit may include a sub board to display operation states. The main board and the sub board may be connected by the elastic cable.

In accordance with example embodiments, a method for manufacturing an elastic cable including a plurality of conductor tracks and elastic insulating films may include supplying the plurality of conductor tracks, aligning the plurality of conductor tracks by an aligning unit such that the conductor tracks are uniformly spaced apart from one another, supplying the elastic films such that the elastic films support the plurality of conductor tracks, supplying the plurality of conductor tracks supported by the elastic films to a thermal lamination roller unit, and laterally reciprocating the aligning unit while applying a constant tension to the plurality of conductor tracks.

The plurality of conductor tracks may be shaped to have a zigzag shape by varying a lateral moving speed and length of the aligning unit and a rotation speed of the thermal lamination roller unit.

The elastic films may be made of elastic polymer, rubber, or a composite thereof.

Each of the conductor tracks may include an elastic core, and a conductive metal wire wound around the core.

The aligning unit may include a plurality of aligners to independently move, in a lateral direction, the plurality of conductor tracks, respectively. The plurality of conductor tracks may be shaped to have a zigzag shape as the aligners are independently moved.

### BRIEF DESCRIPTION OF THE DRAWINGS

These and/or other aspects of example embodiments will become apparent and more readily appreciated from the following description, taken in conjunction with the accompanying drawings of which:

FIG. 1 is a perspective view schematically illustrating a structure of an elastic cable according to example embodiments;

FIG. 2 is a perspective view schematically illustrating various examples of the elastic cable according to example embodiments;

FIG. 3 is a side view schematically illustrating an apparatus for manufacturing the elastic cable in accordance with example embodiments;

FIG. 4 is a plan view schematically illustrating the elastic cable manufacturing apparatus according to example embodiments;

FIG. 5 is a plan view schematically illustrating an apparatus for manufacturing the elastic cable in accordance with example embodiments;

FIG. 6 schematically illustrates an apparatus for manufacturing an elastic cable having a multilayer structure in accordance with example embodiments; and

FIGS. 7 to 9 are views illustrating application examples of an elastic cable according to example embodiments.

### DETAILED DESCRIPTION

Example embodiments will now be described more fully with reference to the accompanying drawings, in which example embodiments are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the sizes of components may be exaggerated for clarity.

It will be understood that when an element or layer is referred to as being “on”, “connected to”, or “coupled to” another element or layer, it can be directly on, connected to, or coupled to the other element or layer or intervening elements or layers that may be present. In contrast, when an element is referred to as being “directly on”, “directly connected to”, or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. Thus, a first element, component, region, layer, or section discussed below could be termed a second element, component, region, layer, or section without departing from the teachings of example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments described herein will refer to plan views and/or cross-sectional views by way of ideal schematic views. Accordingly, the views may be modified depending on manufacturing technologies and/or tolerances. Therefore, example embodiments are not limited to those shown in the views, but include modifications in configuration formed on the basis of manufacturing processes. Therefore, regions exemplified in figures have schematic properties and shapes of regions shown in figures exemplify specific shapes or regions of elements, and do not limit example embodiments.

Reference will now be made in detail to example embodiments, examples of which are illustrated in the accompanying drawings, wherein like reference numerals refer to like elements throughout.

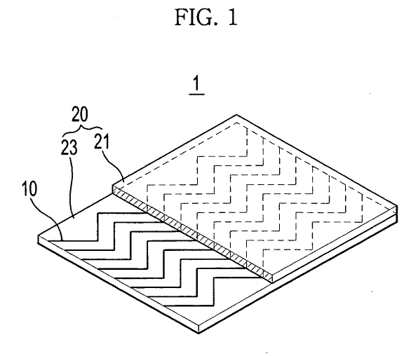

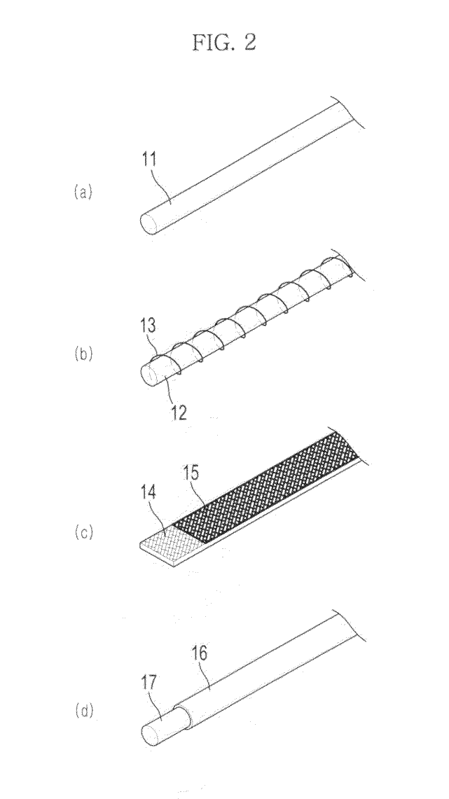

FIG. 1 is a perspective view schematically illustrating a structure of an elastic cable according to example embodiments. FIG. 2 illustrates various examples of the elastic cable according to example embodiments.

Referring to FIG. 1, the elastic cable 1 may include conductor tracks 10 arranged in parallel in a width direction of the elastic cable 1. Each conductor track 10 may be bent in a zigzag shape. The elastic cable 1 may also include a foil-shaped film 20 as an insulator. In example embodiments, the film 20 may cover the conductor tracks 10.

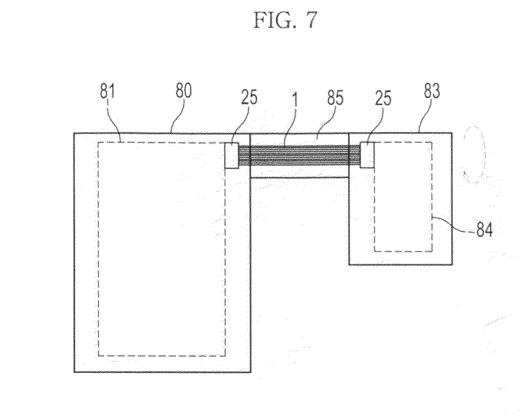

Each conductor track 10 may have a relatively small thickness or diameter (about 0.01 to 0.5 mm). Each conductor track 10 may have opposite ends, each of which may have a structure capable of being connected to a certain connector 25 (FIG. 7) or directly connected to a terminal of a circuit board.

As shown in FIG. 2(a), each conductor track 10 may be formed using a conductive metal wire 11. Alternatively, as shown in FIG. 2(c), each conductor track 10 may be formed using a conductive yarn including a core 14. The core 14, for example, may be a non-conductive fiber or polymer thread. In example embodiments, a conductive metal 15 may be coated over the surface of the core 14. In the alternative, a yarn bundle may be formed by twisting a plurality of conductive yarns having the above-described structure. The conductive metal 15 may be copper, silver, gold, platinum, iron, nickel, or the like.

As shown in FIG. 2(d), each conductive track 10 may also be formed using a conductive metal wire 17 surrounded by a non-conductive material 16. In example embodiments, to the non-conductive material 16 may prevent or retard the conductor track 10 from being short-circuited during a manufacturing process.

Also, as shown in FIG. 2(b), each conductive track 10 may include an elastic core 12, and a conductive metal wire 13 wound around the core 12. The elastic core 12 may be made of an elastically-deformable non-conductive material, for example, silicon, polyurethane (PU), or synthetic rubber.

In example embodiments, it may be possible to more efficiently prevent or retard a short circuit of the conductive track 10, which may occur when the cable 1 is stretched or contracted.

The film 20 may be made of a foil-shaped polymer or rubber having elasticity, or a composite thereof. The film 20 may include upper and lower films 21 and 23 surrounding the conductor tracks 10 arranged in parallel and bent in a zigzag shape. For the elastic polymer, polyurethane (PU) may be used.

In accordance with such a configuration, the elastic cable 1 may secure high reliability because the zigzag-shaped conductor tracks 10 interposed between the upper and lower films 21 and 23 of the film 20 are stretched or contracted when the elastic cable 1 is deformed due to external stresses such as bending, tension, compression, and torsion.

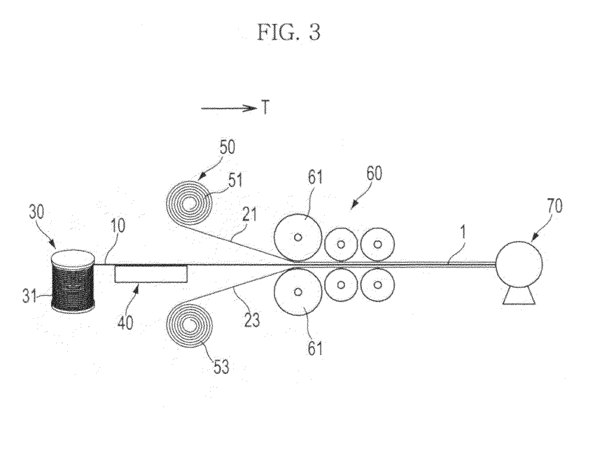

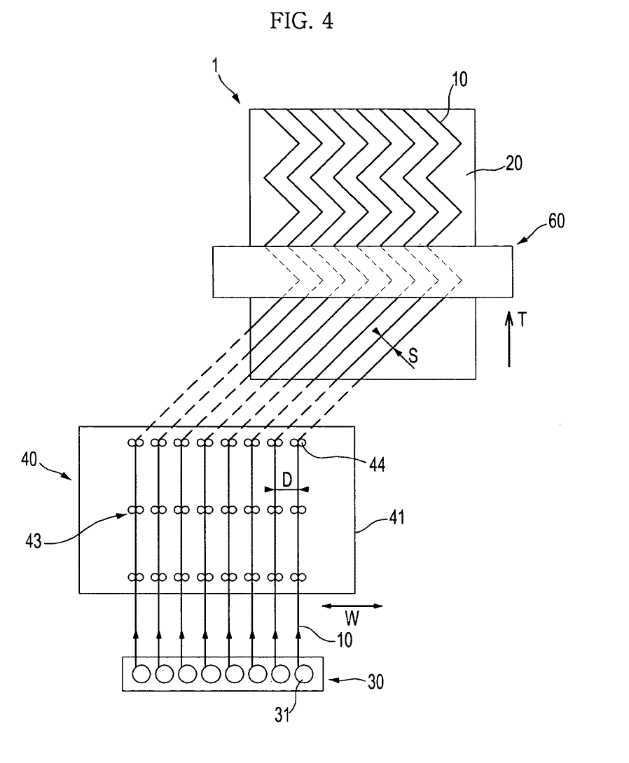

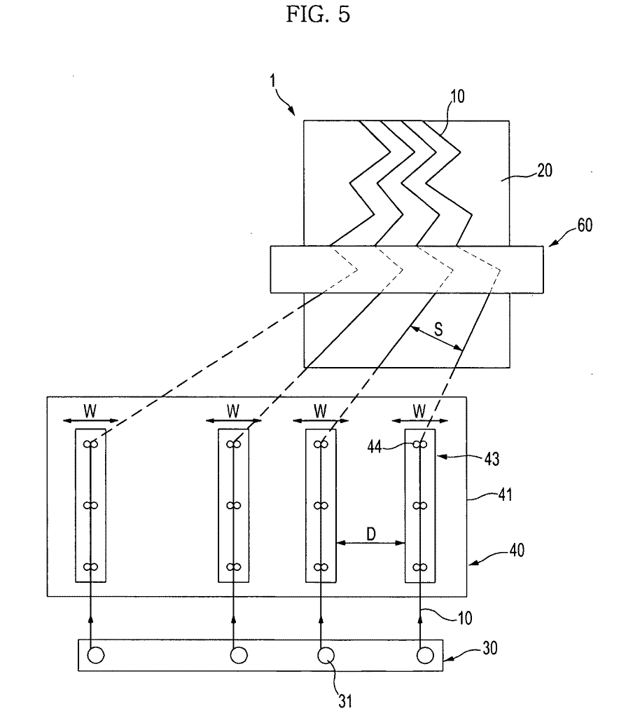

FIG. 3 is a side view schematically illustrating an apparatus for manufacturing the elastic cable in accordance with example embodiments. FIG. 4 is a plan view schematically illustrating the elastic cable manufacturing apparatus according to example embodiments. FIG. 5 is a plan view schematically illustrating an apparatus for manufacturing the elastic cable in accordance with example embodiments.

The elastic cable manufacturing apparatus shown in FIG. 3 may include a conductor track supplying unit 30 to supply conductor tracks 10, which may be arranged in parallel in a width direction of an elastic cable 1, in a certain feeding direction T, an aligning unit 40 to align the conductor tracks 10 supplied from the conductor track supplying unit 30, and a film supplying unit 50 to supply the elastic films 21 and 23, which may surround upper and lower surfaces of the conductor tracks 10 fed from the aligning unit 40. The elastic cable manufacturing apparatus may also include a thermal lamination roller unit 60 to thermally laminate the zigzag-shaped conductor track 10 arranged in parallel between the upper and lower elastic films 21 and 23 supplied by the film supplying unit 50, thereby bonding the conductor track 10 to the upper and lower elastic films 21 and 23, and a receiving unit 70 to receive the resulting elastic cable 1 emerging from the thermal lamination roller unit 60.

The conductor track supplying unit 30 may include a plurality of rolls 31 arranged in parallel. The conductor tracks 10, which may have one of the above-described shapes, may be wound around the rolls 31, respectively. The conductor tracks 10 wound around respective rolls 31 may be fed to the aligning unit 40 after being unwound from the rolls 31 so that they will be aligned by the aligning unit 40.

The conductor track supplying unit 30 may further include uncoilers to allow the conductor tracks 10 to be unwound from the rolls 31 in a state of being tensed by a certain tension.

As shown in FIG. 4, the aligning unit 40 may function to align the conductor tracks 10 supplied from the conductor track supplying unit 30 in a zigzag shape when the conductor tracks 10 are laminated between the upper and lower films 21 and 23. The aligning unit 40 may include a base frame 41 movable in a lateral direction W perpendicular to the feeding direction T of the film 20 by a driver (not shown), and an aligner 43 arranged at the base frame 41, to adjust a spacing S between adjacent ones of the conductor tracks 10 arranged in parallel between the upper and lower films 21 and 23 while applying a constant tension to the conductor tracks 10.

The driver (not shown), which laterally drives the base frame 41, may include a reversible motor, and an actuator to linearly reciprocate through a spiral screw, for example, a lead screw, a rack-and-pinion, or a linear motion guide.

The aligner 43 may include a plurality of pressing rollers 44 arranged in pairs on an upper surface of the base frame 41 in the feeding direction T for each conductor track 10. The corresponding pairs of the pressing rollers 44 for respective conductor tracks 10 may be spaced apart from one another in the lateral direction W by a distance D. The pressing rollers 44 of each roller pair may function to press opposite sides of the corresponding conductor track 10, respectively.

In accordance with this configuration, each conductor track 10 is in a constantly-tensioned state between the aligning unit 40 and the thermal lamination roller unit 60. Accordingly, the spacing S between adjacent ones of the conductor tracks 10, which are supplied in a zigzag shape to the thermal lamination roller unit 60 by the base frame 41 moving laterally by the driver, may be maintained.

Although the aligner 43 may include the pairs of pressing rollers 44 each pressing the opposite sides of the corresponding conductor track 10, example embodiments, as illustrated in FIG. 4, are not limited thereto. Other structures may be used for the aligner 43, so long as they can guide the conductor tracks 10 while constantly applying a certain tension to the conductor tracks 10.

Although the aligning unit 40 may include the aligner 43, which may include a plurality of pressing rollers fixedly mounted on the upper surface of the laterally-movable base frame 41, to maintain the spacing D between the adjacent conductor tracks 10 during the feeding of the conductor tracks 10, in the case of FIG. 4, a plurality of aligners 43 may be provided to independently move, in the lateral direction W, respective conductor tracks 10 supplied from the conductor track supplying unit 30, as shown in FIG. 5.

That is, a plurality of aligners 43, which are independently movable, may be arranged on the base frame 41. In example embodiments, the base frame 41 may have a fixed structure.

Using the aligner 43 or aligners 43, it may be possible to adjust the spacing S of the conductor tracks 10 interposed between the films 21 and 23, or the pitch and amplitude of the conductor tracks 10. Accordingly, the size of the elastic cable 1 may be varied.

As a result, the manufacture of the elastic cable 1 may be achieved, irrespective of the size and elasticity of the elastic cable 1, without using a separate device. Thus, an enhancement in productivity may be achieved.

Although a plurality of aligners 43 may be arranged on the fixed base frame 41 such that they are individually movable in the lateral direction W in the case of FIG. 5, the base frame 41 may also be movable in the lateral direction W independently of the aligners 43.

In example embodiments, elastic cables 1 having various shapes may be manufactured. Also, where the elastic cable 1 includes a plurality of conductor tracks 10, which are arranged between films 21 and 23 while maintaining a certain spacing S between the adjacent conductor tracks 10, the manufacture of the elastic cable 1 may be achieved by varying the spacing D between the adjacent conductor tracks 10 during the feeding of the conductor tracks 10 in accordance with the size of the elastic cable 1 by the aligners 43, and then moving the base frame 41 in the lateral direction W in a fixed state of the aligners 43. In example embodiments, accordingly, it may be possible to reduce the power consumption of the driver.

The film supplying unit 50 may supply the upper and lower elastic films 21 and 23 to positions over and beneath the conductor tracks 10 supplied from the aligning unit 40, respectively. The film supplying unit 50 may include upper and lower film rolls 51 and 53, around which the elastic films 21 and 23 are wound.

The conductor tracks 10 supplied from the aligning unit 40 may be interposed between the upper and lower films 21 and 23 emerging from the film supplying unit 50, and supplied to the thermal lamination roller unit 60.

The thermal lamination roller unit 60 may function to thermally laminate the conductor tracks 10 interposed between the upper and lower films 21 and 23. The thermal lamination roller unit 60 may include a pair of lamination rollers 61 vertically arranged to face each other. If necessary, an increased number of lamination rollers 61 may be used.

The conductor tracks 10 interposed between the elastic films 21 and 23 may be heated to a certain temperature (about 80° C. to about 300° C.) in a state of being pressed by the lamination rollers 61 while passing through a nip defined between the lamination rollers 61. As a result, the conductor tracks 10 may be bonded between the elastic films 21 and 23.

The elastic cable manufacturing apparatus may further include an adhesive coater to coat an adhesive having elasticity between the upper and lower films 21 and 23, in order to achieve easy bonding of the elastic films 21 and 23 when they are pressed by the lamination rollers 61.

The receiving unit 70 may include a winder to wind a product supplied from the thermal lamination roller unit 60 after being completely manufactured by thermally laminating the conductor tracks 10 interposed between the elastic films 21 and 23 in the thermal lamination roller unit 60, namely, the elastic cable 1.

Thus, the manufacturing apparatus may have a simple configuration in that it may be possible to form the conductor tracks 10 in a zigzag shape in accordance with lateral reciprocating movements of the aligning unit 40 when the conductor tracks 10 are supplied to a nip defined between the thermal lamination rollers 61 of the thermal lamination roller unit 60 so that the conductor tracks 10 are laminated between the elastic films 21 and 23.

The amplitude, pitch, and curvature of the zigzag-shaped conductor tracks 10 may be varied in accordance with the lateral movement speed and length of the aligning unit 40 and the rotation speed of the thermal lamination rollers 61. Accordingly, the conductor tracks may have various zigzag shapes.

Where the aligners 43 to align respective conductor tracks 10 are laterally movable in an individual manner, it may be possible to implement more diverse shapes of conductor tracks 10 and more diverse spacings of conductor tracks 10. Accordingly, it may be possible to manufacture elastic cables 1 having various sizes without using an additional device.

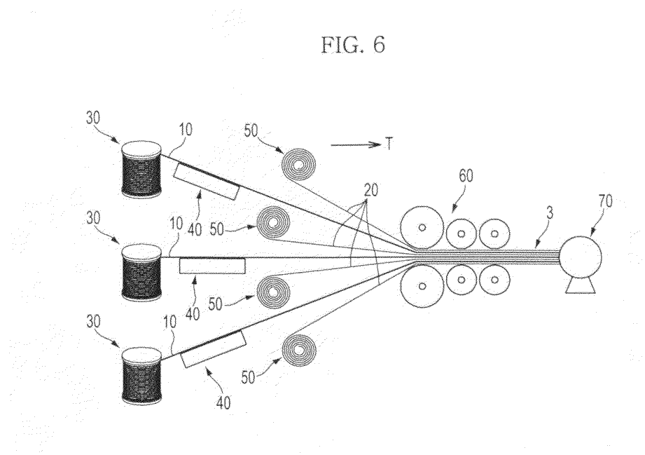

FIG. 6 schematically illustrates an apparatus for manufacturing an elastic cable having a multilayer structure in accordance with example embodiments. In example embodiments, constituent elements having the same functions as those previously described will be designated by the same reference numerals, and no detailed description thereof will be given.

As shown in FIG. 6, the manufacturing apparatus, which manufactures an elastic cable 3 having a multilayer structure, may include a plurality of film supplying units 50 arranged to supply films 20, which will form a plurality of layers. The manufacturing apparatus may also include a plurality of conductor track supplying units 30 to supply a plurality of conductor tracks 10 such that the conductor tracks 10 are arranged in parallel between adjacent ones of the films 20, and a plurality of aligning units 40 to align the conductor tracks 10 supplied between the adjacent films 20.

In accordance with this configuration, the conductor tracks 10, which may be supplied in a zigzag shape between adjacent ones of the multilayered films 20, may be laminated and bonded as they pass a nip defined between the thermal lamination rollers 61. Thus, an elastic cable 3 having a multilayer structure may be manufactured.

FIGS. 7 to 9 illustrate application examples of an elastic cable according to example embodiments.

As shown in FIGS. 7 to 9, the elastic cable 1 may be applied to an electronic appliance, for example, a robot, a mobile phone, a notebook, or a camcorder, which may include a fixed unit 80 and a movable unit 83 movable with respect to the fixed unit 80.

The fixed unit 80 may include a main board to supply electric power to the movable unit 83 and to generate various control signals to be supplied to the movable unit 83. The movable unit 83 may include a sub board 84 to control operations of various elements such as motor and a display in accordance with signals sent from the main board 81, and to display operation states of the elements.

The supply of electric power and transfer of control signals from the main board 81 to the sub board 84 may be carried out using the elastic cable 1.

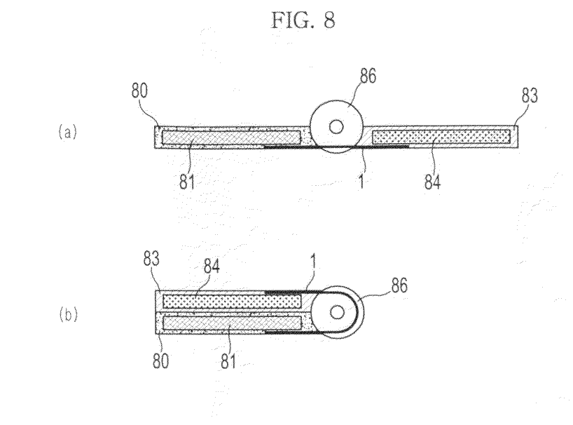

As shown in FIG. 7, the movable unit 83, which may be movable with respect to the fixed unit 80, may be rotatable about a rotating shaft 85 in a swivel type. Alternatively, as shown in FIG. 8, the movable unit 83 may be rotatable about a rotating shaft 86 in a folder type with respect to the fixed unit 80.

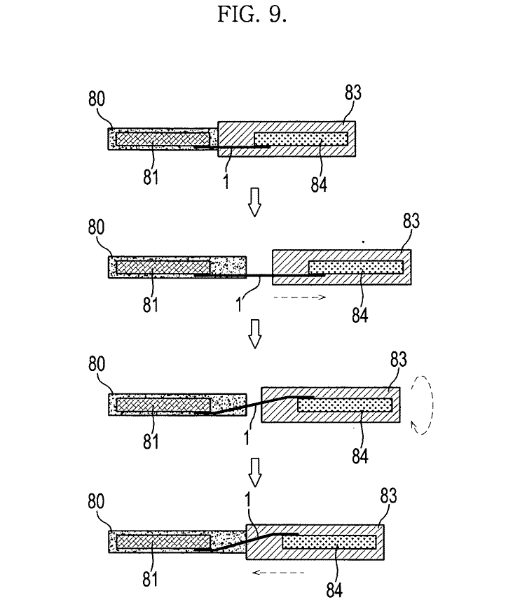

Also, as shown in FIG. 9, the movable unit 83 may be rotatable within a certain angle (for example, about 0 to about 180°) after being separated from the fixed unit 80, and then again coupled to the fixed unit 80.

During the movement of the movable unit 83 with respect to the fixed unit 80, external stresses due to bending, tension, compression, and torsion may be applied to the elastic cable 1 connected, at opposite ends thereof, between the fixed unit 80 and the movable unit 83. However, the rotation of the movable unit 83 may be freely carried out without a limitation of a rotation radius thereof caused by the elastic cable 1 because the elastic cable 1 has elasticity and flexibility.

Also, it may be unnecessary to provide a separate movement space to allow for stretching and contraction of the cable 1 during the rotation of the movable unit 83. As a result, the volume of the connecting portions may be reduced or minimized. Thus, a product having a miniature and slim structure may be obtained.

Although not shown, the elastic cable may be used to connect circuit boards or the like in a flexible display, to which bending, tension, compression, and torsion may be applied, or in a computer including a plurality of flexible circuit boards.

As apparent from the above description, the elastic cable may have enhanced reliability against external stresses because it is elastic. Also, where the elastic cable is used in an electronic appliance including a movable unit, it may have a slim and miniature structure at connection parts thereof.

Although example embodiments have been shown and described, it would be appreciated by those skilled in the art that changes may be made in example embodiments without departing from the principles and spirit of the invention, the scope of which is defined in the claims and their equivalents.

What is claimed is:

1. An apparatus for manufacturing an elastic cable, comprising:
a conductor track supplying unit to supply at least one conductor track;
an aligning unit to align the at least one conductor track supplied from the conductor track supplying unit;
a film supplying unit to supply elastic films such that the at least one conductor track is surrounded by the elastic films; and
a thermal lamination roller unit to thermally laminate the at least one conductor track arranged between the elastic films,
wherein the aligning unit is reciprocally movable to arrange the at least one conductor track in a zigzag shape between the elastic films when the at least one conductor track is supplied to the thermal lamination roller unit.

2. The apparatus according to claim 1, wherein
the at least one conductor track is a plurality of conductor tracks, and
the aligning unit includes a base frame and an aligner arranged at the base frame to adjust a spacing between adjacent conductor tracks of the plurality of conductor tracks and to arrange the plurality of conductor tracks in parallel between the elastic films while tensing the plurality of conductor tracks when the plurality of conductor tracks are supplied to the thermal lamination roller unit.

3. The apparatus according to claim 2, wherein at least one of the base frame and the aligner is laterally reciprocable.

4. The apparatus according to claim 3, wherein the aligner includes a plurality of pressing rollers arranged on an upper surface of the base frame while being spaced apart from one another by a distance.

5. The apparatus according to claim 3, wherein the aligning unit is a reciprocable aligning unit configured to have a variable moving speed.

6. The apparatus according to claim 1, wherein the at least one conductor track is a conductive yarn comprising a core made of one of a non-conductive fiber and a polymer thread, and a conductive metal coated over a surface of the core.

7. The apparatus according to claim 1, wherein the at least one conductor track is a conductive metal wire surrounded by a non-conductive material.

8. The apparatus according to claim 1, wherein the at least one conductor track includes an elastic core and a conductive metal wire wound around the core.

9. The apparatus according to claim 1, wherein the thermal lamination roller unit includes thermal lamination rollers maintained at about 80 to about 300° C.

10. The apparatus according to claim 1, wherein the film supplying unit is provided in plural to supply films, which will form a plurality of layers, the conductor track supplying unit is provided in plural to supply the at least one conductor track as a plurality of conductive tracks between adjacent ones of the films, and the aligning unit is provided in plural to align the plurality of conductor tracks supplied between the adjacent films.

11. The apparatus according to claim 1, further comprising:
an adhesive coater to coat an adhesive between the elastic films.

12. An electronic appliance comprising:
a fixed unit;
a movable unit coupled to the fixed unit such that the movable unit is movable with respect to the fixed unit; and
an elastic cable connecting the fixed unit and the movable unit, wherein the elastic cable includes a plurality of conductor tracks arranged in parallel in a width direction in a zigzag shape between elastic films.

13. The electronic appliance according to claim 12, wherein the movable unit is rotatable about a rotating shaft in a swivel type with respect to the fixed unit.

14. The electronic appliance according to claim 12, wherein the movable unit is rotatable about a rotating shaft in a folder type with respect to the fixed unit.

15. The electronic appliance according to claim 12, wherein the movable unit is rotatable in a state of being separated from the fixed unit, and is coupled to the fixed unit after the rotation.

16. The electronic appliance according to claim 12, wherein the fixed unit includes a main board configured to supply electric power and to generate control signals, the movable unit comprises a sub board configured to display operation states, and the main board and the sub board are connected by the elastic cable.

17. A method for manufacturing an elastic cable including a plurality of conductor tracks and elastic insulating films, comprising:
supplying the plurality of conductor tracks;
aligning the plurality of conductor tracks by an aligning unit such that the plurality of conductor tracks are uniformly spaced apart from one another;
supplying the elastic films such that the elastic films support the plurality of conductor tracks;
supplying the plurality of conductor tracks supported by the elastic films to a thermal lamination roller unit; and
laterally reciprocating the aligning unit while applying a constant tension to the plurality of conductor tracks.

18. The method according to claim 17, wherein the plurality of conductor tracks are shaped to have a zigzag shape by varying a lateral moving speed.

19. The method according to claim 18, wherein each of the conductor tracks includes an elastic core and a conductive metal wire wound around the core.

20. The method according to claim 17, wherein the aligning unit includes a plurality of aligners to independently move, in a lateral direction, the plurality of conductor tracks, respectively, and the plurality of conductor tracks are shaped to have a zigzag shape as the aligners are independently moved.
